(19) United States
(12) Patent Application Publication
(10) Pub. No.: US 2015/0036419 A1
(43) Pub. Date: Feb. 5, 2015

(54) SEMICONDUCTOR APPARATUS AND DATA READING METHOD

(71) Applicant: Renesas Electronics Corporation, Kawasaki-shi (JP)

(72) Inventors: Yuichiro Ishii, Kawasaki-shi (JP); Atsuo Yoneyama, Yokohama-shi (JP); Nobusuke Tada, Yokohama-shi (JP)

(21) Appl. No.: 14/331,025

(22) Filed: Jul. 14, 2014

(30) Foreign Application Priority Data
Jul. 31, 2013 (JP) 2013-159414

(51) Int. Cl. G11C 11/419

(52) U.S. Cl. CPC G11C 11/419
USPC 365/154

(57) ABSTRACT

A semiconductor apparatus includes a memory array that is disposed such that bit line pairs are arranged in a plurality of columns in a column direction and the bit line pairs are connected to one data latch circuit, in which a plurality of memory cells are connected to the bit line pair, a precharge circuit that blocks precharge of a bit line pair that is selected by a column address signal among the plurality of bit line pairs and precharges the bit line pairs other than the bit line pair selected by the column address signal, and a data latch circuit that outputs read data from the memory array based on potentials of a first bit line and a second bit line, in which the first bit line constitutes a first bit line pair, and the second bit line pair constitutes a second bit line pair.

### CROSS-REFERENCE TO RELATED APPLICATIONS

This application is based upon and claims the benefit of priority from Japanese patent application No. 2013-159414, filed on Jul. 31, 2013, the disclosure of which is incorporated herein in its entirety by reference.

### BACKGROUND

The present invention relates to a semiconductor apparatus and a data reading method.

In a microcomputer and SOC (System On Chip), a built-in SRAM (Static Random Access Memory) has widely been used. Such an SRAM often employs a circuit that processes an amplitude of a bit line by an inverter or the like as a read control circuit from a memory array instead of using a sense amplifier. The read control circuit using an inverter (the read control circuit is also referred to as a data latch circuit) includes a smaller number of elements than a sense amplifier does, and thus the circuit area can be reduced. Configuration examples not using a sense amplifier are disclosed in, for example, Japanese Unexamined Patent Application Publication Nos. H10-340584, 2000-207886, 2004-318970, and 2012-43502.

In such an SRAM configuration (a configuration in which an inverter or the like is used as the read control circuit), in consideration of a relationship among adjustment of an aspect ratio of an SRAM macro, layout ability of an I/O unit, and a maximum bit line length, a memory array is configured in such a way that memory cells are arranged in a column direction. To be more specific, such an SRAM has a configuration in which a plurality of bit line pairs arranged in the column direction are connected to the same read control circuit. Thus, the SRAM macro includes column switching circuits that switch a bit line which is to be selected for each of the read control circuit and a data write circuit in the I/O unit. The SRAM macro includes a timing generation circuit that generates various control signals (an address predecode signal, a column address signal, a write address signal, a read enable signal, and a write enable signal). The timing generation circuit supplies the column address signal to both of the column switching circuits.

### SUMMARY

As described above, in an SRAM configuration using an inverter and the like as a read control circuit, column switching circuits are included that correspond to each of a read control circuit and a data write circuit. The present inventor has found a problem that as the column switching circuits corresponding to each of the read control circuit and the data write circuit are included, the number of elements increases.

Other problems and new features will be apparent from the description of the specification and attached drawings of the present invention.

According to an aspect, a semiconductor apparatus includes a memory array that is disposed such that bit line pairs are arranged in a plurality of columns in a column direction and the bit line pairs in the plurality of columns are connected to one data latch circuit, in which a plurality of memory cells are connected to the bit line pair, the semiconductor apparatus blocks precharge of a bit line pair that is selected by a column address signal, and outputs read data from the memory array based on potentials of respective bit lines constituting the plurality of bit line pairs that are arranged in the column direction.

According to the above aspect, it is possible to read data from the memory array by a small number of elements.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing a configuration of a semiconductor apparatus 1 according to a first embodiment;

FIG. 2 is a diagram showing a configuration in a logical address space of a memory array 30 according to the first embodiment;

FIG. 3 is a diagram showing a physical arrangement of the memory array 30 according to the first embodiment;

FIG. 4 is a diagram showing a configuration example of a memory cell according to the first embodiment;

FIG. 5 is a block diagram showing a detailed configuration of a precharge circuit 40, a write driver 50, and a column switching circuit 60 according to the first embodiment;

FIG. 6 is a block diagram showing a configuration of a data latch circuit 70 according to the first embodiment;

FIG. 7 is a timing chart showing read processing of the semiconductor apparatus 1 according to the first embodiment;

FIG. 8 is a block diagram showing a configuration of the semiconductor apparatus 1 according to the second embodiment;

FIG. 9 is a diagram showing a layout configuration of the semiconductor apparatus according to the second embodiment;

FIG. 10 is a block diagram showing a detailed configuration of a precharge circuit 40, a write driver 50, and a column switching circuit 60 according to another embodiment; and

FIG. 11 is a block diagram showing a configuration of a data latch circuit 70 according to the other embodiment.

### DETAILED DESCRIPTION

First Embodiment

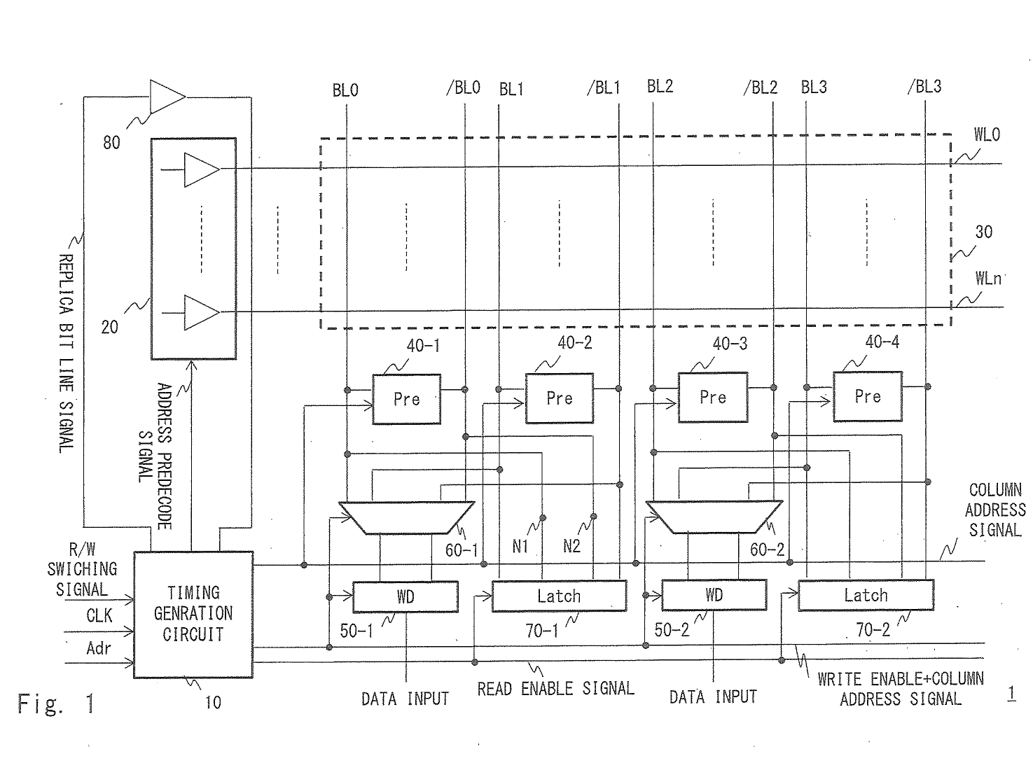

Hereinafter, a semiconductor apparatus according to the first embodiment shall be explained in detail with reference to the drawings. FIG. 1 shows a configuration of a semiconductor apparatus 1 according to the first embodiment. The semiconductor apparatus 1 is, for example, an SRAM (Static Random Access Memory) circuit. Note that the target SRAM circuit may either be a single-port SRAM circuit or a multi-port SRAM circuit.

The semiconductor apparatus 1 includes a timing generation circuit 10, a word line driver 20, a memory array 30, precharge circuits 40-1 to 40-4, write drivers 50-1 and 50-2, column switching circuits 60-1 and 60-2, data latch circuits 70-1 and 70-2, and a NOT circuit 80. In the following explanation, circuits having substantially the same components shall be denoted using “-” (e.g., the precharge circuits 40-1 and 40-2), while in the description that applies to those circuits having substantially the same components, the circuits shall be denoted without using “-” (e.g., the precharge circuit 40).

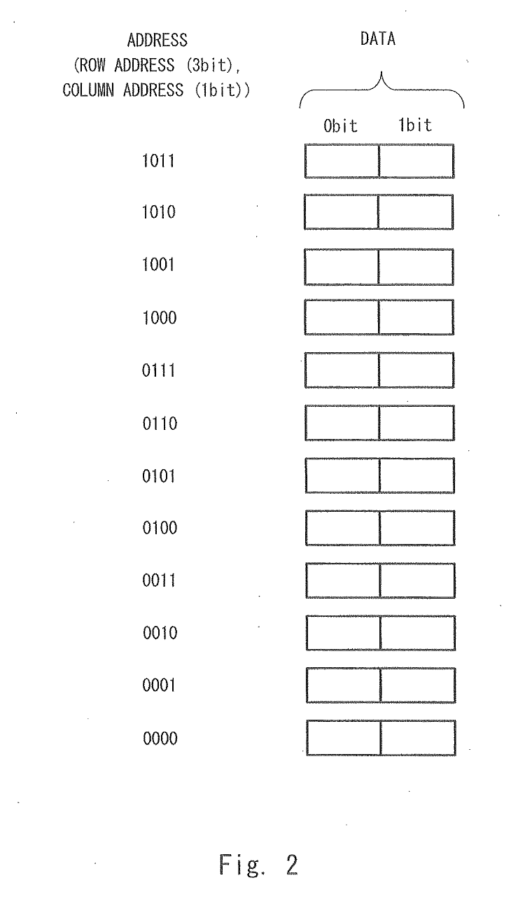

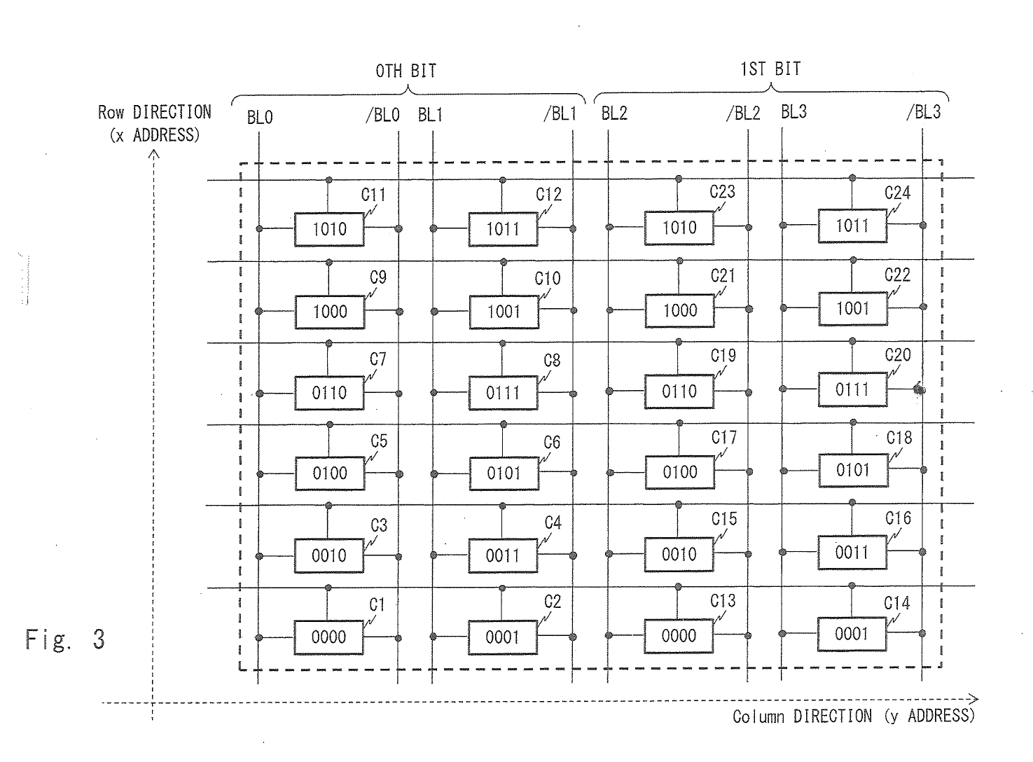

The memory array 30 includes a plurality of memory cells (not shown in FIG. 1) that are integrated and arranged in a matrix. A configuration and a physical arrangement configuration of the memory array 30 in a logical address space shall be explained with reference to FIGS. 2 and 3.

FIG. 2 is a diagram showing a configuration of the memory array 30 in a logical address space. In this example, assume that two-bit length data is stored to each address. The bit length of the address is four bits, in which the first three bits constitute a row address and the last one bit constitutes a column address.

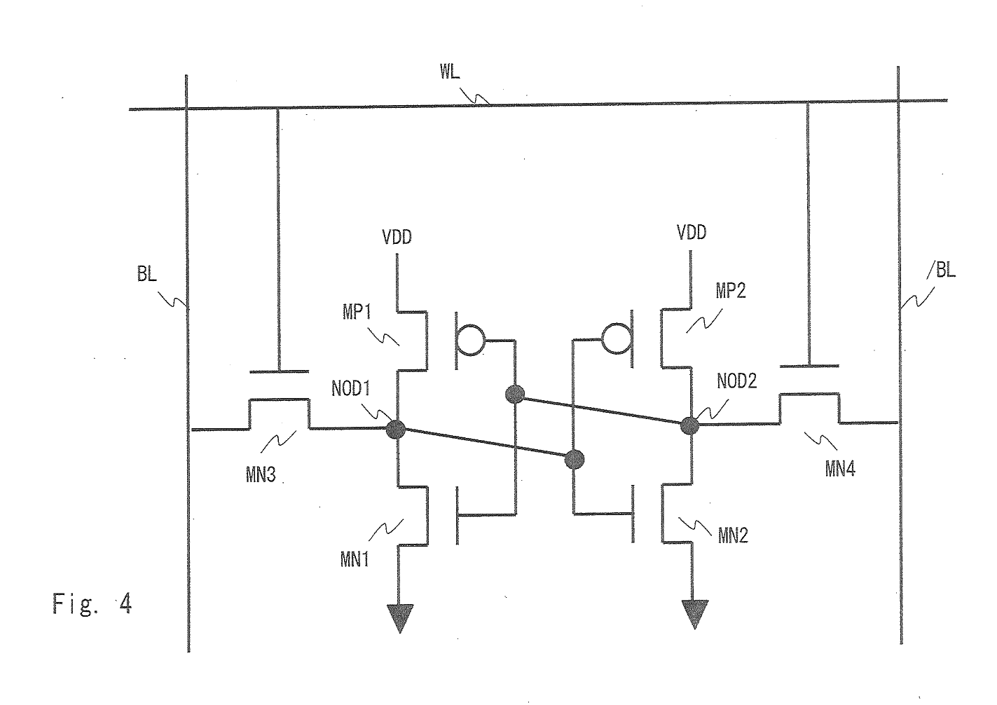

FIG. 3 is a diagram showing a physical arrangement of the memory array 30. The memory array 30 includes a plurality of memory cells (in the case of FIG. 3, memories C1 to C24) that are connected to bit line pairs. In the drawings, addresses (e.g., “0000”) are illustrated together with the respective memory cells. Note that the arrangement of the memory cells in FIG. 3 is merely an example, and the number of the memory cells held in the memory array 30 may be any number. FIG. 4 shows an example showing a configuration of one of the memory cells.

As shown in FIG. 4, each memory cell includes two inverters (a first inverter and a second inverter) that constitute a latch circuit and two access MOS transistors (MN3 and MN4 which are NMOS). The first inverter includes a driver transistor MN1 and a load transistor MP1. The second inverter includes a driver transistor MN2 and a load transistor MP2.

Inputs and outputs of the first inverter and the second inverter are connected to each other. A first memory node NOD1 is connected to a first terminal of the MN3. A second memory node NOD2 is connected to a first terminal of the MN4. The gate of the MN3 is connected to a word line WL. The gate of the MN4 is connected to the word line WL. A second terminal of the MN3 is connected to a bit line EL. A second terminal of the MN4 is connected to a bit line /BL.

The source of the MP1 is connected to a power supply terminal VDD, and the drain of the MP1 is connected to the first memory node NOD1. The source of the MP2 is connected to the power supply terminal VDD, and the drain of the MP2 is connected to the second memory node NOD2. The source of the MN1 is connected to GND, and the drain of the MN1 is connected to the first memory node NOD1. The source of the MN2 is connected to the GND, and the drain of the MN2 is connected to the second memory node NOD2. Note that the configuration shown in FIG. 4 is an example of the memory cell, and the memory cell can have other configurations.

Refer back to FIG. 3. A plurality of bit line pairs (BL0-/BL0 to BL3-/BL3) are arranged inside the memory array 30. Further, a plurality of word lines (WL0 to WL5) are disposed inside the memory array 30. Note that in the following explanation, a bit line pair composed of BL0 and /BL0 shown in the drawings shall also be referred to as a bit line pair 0. The bit line pairs composed of BL1-/BL1 to BL3-/BL3 shall be referred to in a manner similar to the bit line pair 0.

Each of the memory cells C1 to C24 holds one-bit data. For example, the memory cell C1 holds 0th bit data with the address “0000”. The memory cell C13 holds first bit data with the address “0000”. Therefore, when there is a read access to the address “0000”, the data held in the memory cells C1 and C13 is output.

Referring to FIGS. 1 and 3, the plurality of memory cells are connected to each of the bit line pairs (e.g., the memory cells C1, C3, C5, C7, C9, and C11 are connected to the bit line pair 0). Further, a plurality of bit line pairs are connected to the same data latch circuit 70-1 (the bit line pair 0 (the first bit line pair) and the bit line pair 1 (the second bit line pair)), and each of the bit line pairs is connected to the memory cells that indicate the same bit. For example, the bit line pair 0 and the bit line pair 1 are connected to the memory cells that hold 0th bit data. In other words, the bit line pairs that are connected to the memory cells C1 to C12 that hold the same bit (0th bit) data are arranged in a plurality of columns in the column direction, and those bit line pairs are connected to the same data latch circuit 70-1. A connection relationship between the memory cells C13 to C24, the bit line pairs 3 and 4, and the data latch circuit 70-2 is similar to the one explained above.

Refer back to FIG. 1. A clock signal (CLK), an address signal (Adr), and a read/write (R/W) switching signal are input to the timing generation circuit 10. In response to those signals, the timing generation circuit 10 outputs a read enable signal, a write enable signal, a column address signal, an address predecode signal, and a replica bit line signal.

The address signal indicates an address to be accessed. The read/write switching signal is a signal for switching whether to read or write from or in the memory array 30. That is, the read/write switching signal is regarded as a request signal for reading (a read request signal) and a request signal for writing (a write request signal). The timing generation circuit 10 switches a value of a read enable signal and a write enable signal according to the read/write switching signal. The read enable signal instructs reading when the read enable signal is a high level. Similarly, the write enable signal instructs writing when the write enable signal is a high level.

The column address signal is a signal indicating which column is to be accessed and is generated based on the address signal. The address predecode signal is a signal indicating which word (row) is to be accessed and is generated based on the address signal.

The replica bit line signal is a signal used to make an adjustment so as to let read processing wait until precharge by the precharge circuit 40 is completed. The timing generation circuit 10 outputs the replica bit line signal on loop wiring when the read/write switching signal that instructs reading is input. The timing generation circuit 10 switches a value of the read enable signal to a high level after the replica bit line signal that has been output returns (is input) to the timing generation circuit 10.

The word line driver 20 includes inside a circuit that corresponds to each of the word lines. The word line driver 20 drives any one of the word lines WL0 to WLn according to the address predecode signal and accesses a selected memory cell column.

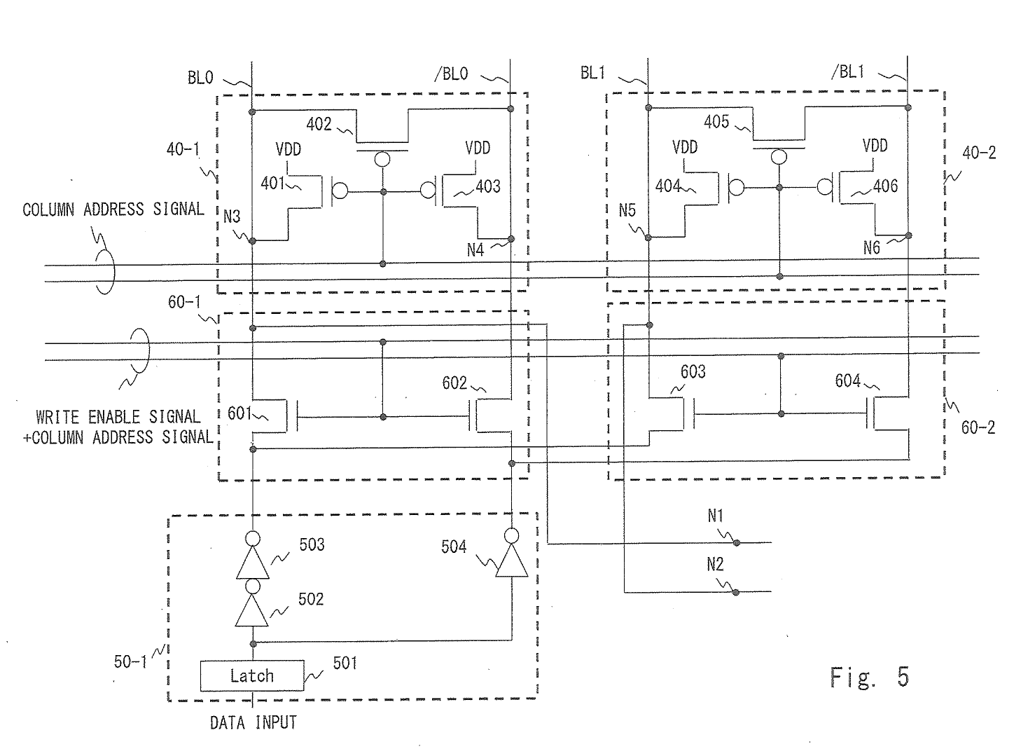

The precharge circuits (40-1 to 40-4) block the bit line pair indicated by the column address signal from being precharged and precharge the bit line pairs other than the bit line pair indicated by the column address signal. In the case of accessing, for example, the memory cell C1 that is connected to the bit line pair 0, the precharge circuit 40-1 blocks precharge, while the precharge circuit 40-2 continues to precharge. Such an operation is performed in order to improve stability of memory cells in the non-selected columns and to avoid an inrush current at the time of resuming the precharge. Then, the bit line pairs of the non-selected columns will become a high level. Meanwhile, as for the bit line pair of the selected column, one of the bit lines becomes high level, and the other bit line becomes a high level. Which one of the bit lines becomes a high level between the bit line pair changes according to the value held in the memory cell which is to be read or written. In this example, when the precharge circuit 40-1 blocks the precharge and the target memory cell holds data “0”, BL0 becomes a high level and /BL0 becomes high level. Meanwhile, when the target memory cell holds data “1”, BL0 becomes high level and /BL0 becomes a high level. The BL1-/BL1 to BL3-/BL3 change in a manner similar to that of BL0-/BL0. A specific configuration of the precharge circuit 40 shall be explained later with reference to FIG. 5.

Data to be written, the column address signal, and the write enable signal are input to the write driver 50. When the write enable signal is a high level, the write driver 50 executes write processing on a column indicated by the column address signal. A specific configuration example of the write driver 50 shall be explained with reference to FIG. 5.

The column address signal and the write enable signal are input to the column switching circuit 60. When the write enable signal is a high level, the column switching circuit 60 writes data in a column indicated by the column address signal. A specific configuration example of the column switching circuit 60 shall be explained with reference to FIG. 5.

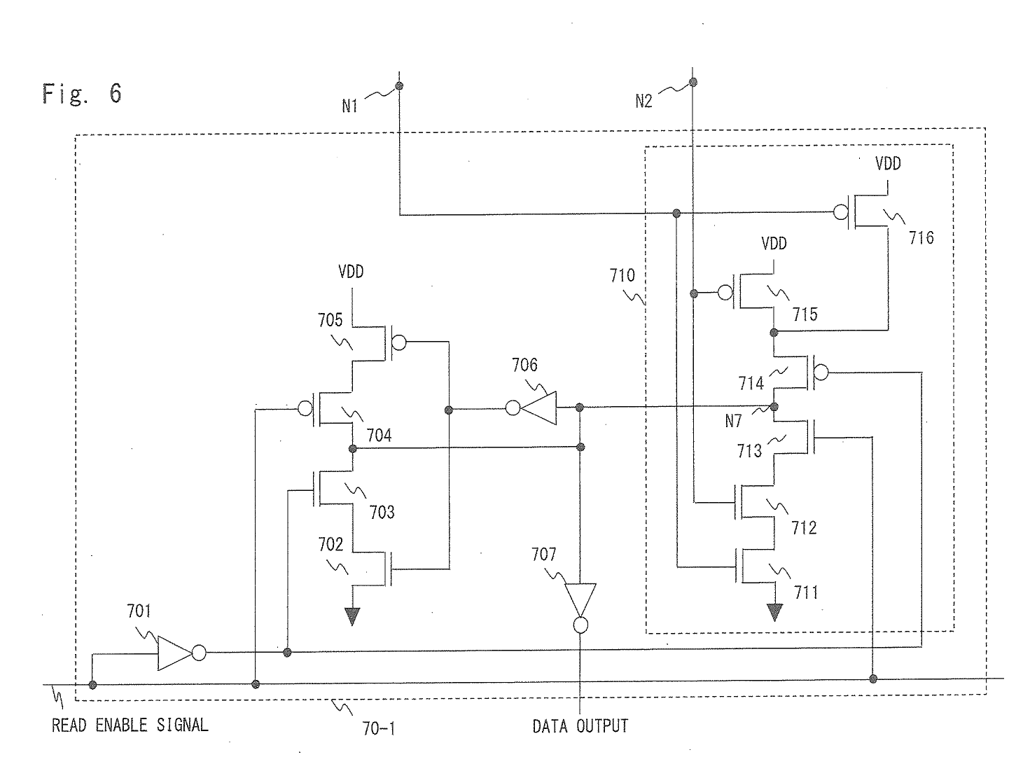

The data latch circuit 70 is connected to the bit line pairs that are arranged in a plurality of columns in the column direction. For example, the data latch circuit 70-1 is connected to the bit line pair 0 (specifically, the bit line BL0 that constitutes the bit line pair 0) and the bit line pair 1 (specifically, the bit line BL1 that constitutes the bit line pair 1). When the read enable signal becomes a high level, the data latch circuit 70 reads data based on a potential of the connected bit line pair. For example, the data latch circuit 70-1 outputs data in a desired memory cell according to potentials of the bit line BL0 and the bit line BL1. In other words, the data latch circuit 70 reads data without using the column address signal. A specific configuration example of the data latch circuit 70 shall be explained with reference FIG. 6.

Next, a specific configuration of the precharge circuit 40 and the like shall be explained with reference to FIG. 5. FIG. 5 is a block diagram showing specific configurations of the precharge circuit 40, the write driver 50, and the column switching circuit 60. The write driver 50-1 includes a latch circuit 501 and NOT circuits 502 to 504.

The latch circuit 501 supplies input data from an external circuit to the NOT circuits 502 and 504. The NOT circuit 504 inverts the input data from the latch circuit 501 and supplies the inverted data to the NMOSs 602 and 604. The NOT circuit 503 supplies the input data from the latch circuit 501 to NMOSs 601 and 603.

The column switching circuit 60-1 includes NMOSs 601 and 602. The NMOS 601 is disposed between an output of the NOT circuit 503 and a node N3 inside the precharge circuit 40-1. The NMOS 602 is disposed between an output of the NOT circuit 504 and a node N4 inside the precharge circuit 40-1. The write enable signal and the column address signal are input to the gate of the NMOS 601 and the gate of the NMOS 602.

Similarly, the column switching circuit 60-2 includes the NMOSs 603 and 604. The NMOS 603 is disposed between the output of the NOT circuit 503 and a node N5 inside the precharge circuit 40-2. The NMOS 604 is disposed between the output of the NMOS circuit 504 and a node N6 inside the precharge circuit 40-2. The write enable signal and the column address signal are supplied to the gate of the NMOS 603 and the gate of the NMOS 604.

When the write enable signal is a high level, the NMOSs 601 to 604 are switched on or off according to the value of the column address signal. When the NMOSs 601 and 602 are switched on, the NMOSs 603 and 604 are switched off, while when the NMOSs 601 and 602 are switched off, the NMOSs 603 and 604 are switched on.

The precharge circuit 40-1 includes PMOSs 401 to 403. The PMOS 401 is disposed between the node N3 and the power supply terminal VDD. The PMOS 402 is disposed between the bit line BL0 and the bit line /BL0. The PMOS 403 is disposed between the node N4 and the power supply terminal VDD. The column address signal is supplied to the gates of the PMOSs 401 to 403.

The PMOSs 401 to 403 are arranged as shown in the drawings such that when the column address signal has a value (a high level) for selecting the bit line pair (BL0 and /BL0), the precharge circuit 40-1 operates in such a way to block precharge of the bit line pair (BL0 and /BL0). That is, when the column address signal has a value for selecting the bit line pair 0, the potential of BL0 differs from that of /BL0. The potential of which bit line between the bit lines constituting the bit line pair becomes a high level changes according to the value of the memory cell connected to BL0 and /BL0.

The precharge circuit 40-2 includes PMOSs 404 to 406. The PMOS 404 is disposed between the node N5 and the power supply terminal VDD. The PMOS 405 is disposed between the bit line BL1 and the bit line /BL1. The PMOS 406 is disposed between the node N6 and the power supply terminal VDD. The column address signal is supplied to the gates of the PMOSs 404 to 406.

Since the PMOSs 404 to 406 are disposed as in the drawings, when the column address signal has a value for selecting the bit line pair (BL1 and /BL1) (i.e. a high level), the precharge circuit 40-2 operates in such a way to block the precharge of the bit line pair 1 (BL1 and /BL1).

Next, a configuration of the data latch circuit 70 shall be explained with reference to FIG. 6. Although FIG. 6 is a block diagram showing a configuration of only the data latch circuit 70-1, the data latch circuit 70-2 has a configuration similar to the data latch circuit 70-1. Firstly, an outline of an operation of the data latch circuit 70 shall be given. As described above, the precharge circuit 40-1 blocks the precharge of the bit line pair which is connected to the selected column while continuing to precharge the bit line pairs other than the bit line pair that is connected to the selected column. For example, when the precharge of the bit line pair 0 is blocked, the bit line pair 1 will continue to be in a precharge state. In other words, the potential of the node N2 (the bit line BL1) will always be a high level, and the potential of the node N1 (the bit line BL0) will be a high level or a low level according to the data held in the memory cell to be accessed. The data latch circuit 70-1 outputs the data held in the memory cell to be accessed by a logical operation using the potentials of the nodes N1 and N2.

Hereinafter, a specific configuration of the data latch circuit 70-1 shall be explained. The data latch circuit 70-1 includes a NOT circuit 701, an NMOS 702, an NMOS 703, a PMOS 704, a PMOS 705, a NOT circuit 706, a NOT circuit 707, and an NAND gate 710. The NAND gate 710 includes NMOSs 711 to 713 and PMOSs 714 to 716.

The NMOS 702 is disposed between the GND and the NMOS 703. The gate of the NMOS 702 is connected to an output of the NOT circuit 706. The NMOS 703 is disposed between the NMOS 702 and the PMOS 704. As the gate of the NMOS 703 is connected to an output of the NOT circuit 701, when the read enable signal is a low level, the NMOS 703 is switched on. The PMOS 704 is disposed between the NMOS 703 and the PMOS 705. As the gate of the PMOS 704 is connected to the read enable signal, when the read enable signal is a low level, the PMOS 703 is switched on. The PMOS 705 is disposed between the PMOS 704 and the power supply terminal VDD. The gate of the PMOS 705 is connected to an output of the NOT circuit 706.

The NOT circuit 706 inverts an output of the NAND gate 710 and supplies the inverted value to the gate of the NMOS 702 and the gate of the PMOS 705. The NOT circuit 707 inverts the output of the NAND gate 710, reads the inverted value, and supplies the inverted value to an external circuit as data.

The NAND gate 710 calculates an NAND value by inputs from the nodes Ni and N2 (i.e., the potential of the bit line BL0 and the potential of the bit line BL1) and supplies the NAND value to the NOT circuits 706 and 707. A configuration of the NAND gate 710 shown in FIG. 6 is an example of outputting the NAND value. An example of the NAND gate 710 shall be explained in detail.

The NMOS 711 is disposed between the GND and the NMOS 712. As the gate of the NMOS 711 is connected to the node N1, when the potential of the node N1 becomes a high level, the NMOS 711 is switched on. The NMOS 712 is disposed between the NMOS 711 and the NMOS 713. As the gate of the NMOS 712 is connected to the node N2, when the potential of the node N1 becomes a high level, the NMOS 712 is switched on.

The NMOS 713 is disposed between the NMOS 712 and the PMOS 714. The node N7, to which the NMOS 713 and PMOS 714 are connected, is connected to an input of the NOT circuit 706 and an input of the NOT circuit 707. As the read enable signal is input to the gate of the NMOS 713, when the read enable signal is a high level, the NMOS 713 is switched on.

The PMOS 714 is connected between the NMOS 713 and the PMOS 715 and the PMOS 716. As an inverted signal of the read enable signal is supplied to the gate of the PMOS 714, when the read enable signal becomes a high level, the PMOS 715 is switched on.

The PMOS 715 is disposed between the PMOS 714 and the PMOS 716 and the power supply terminal VDD. As the gate of the PMOS 715 is connected to the node N2, when the node N2 is a low level, the PMOS 715 is switched on.

The PMOS 716 is disposed between the PMOS 714 and the PMOS 715 and the power supply terminal VDD. As the gate of the PMOS 716 is connected to the node N1, when the node N1 is a low level, the PMOS 716 is switched on.

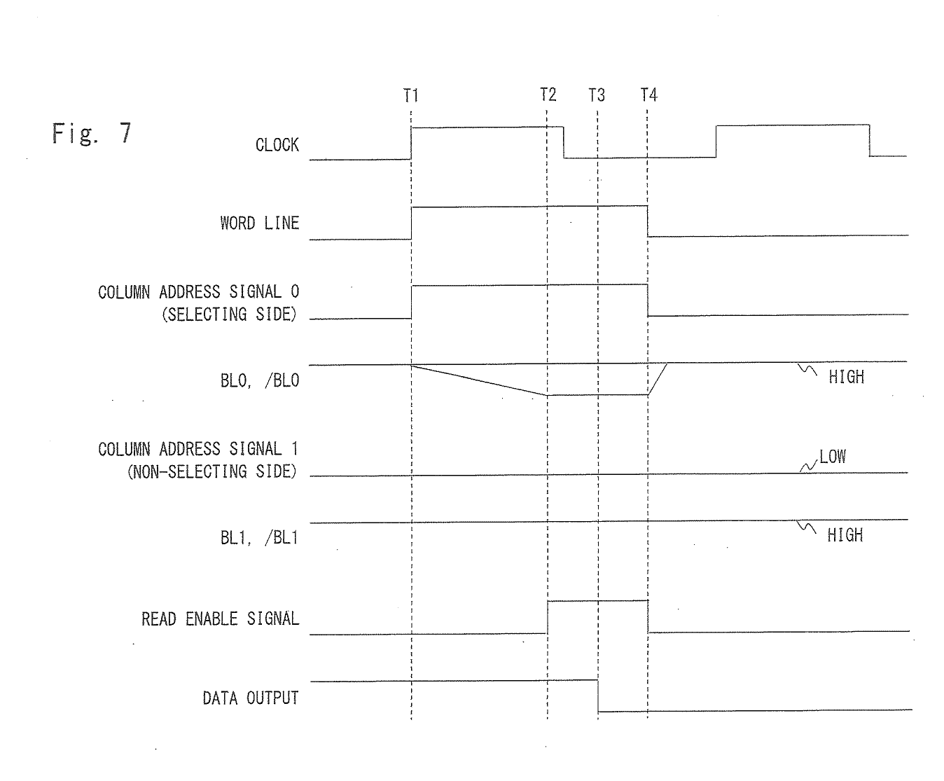

Next, with reference to the timing chart of FIG. 7, an explanation of an operation in the case of reading data from a memory cell of a column address=0 shall be explained. A clock signal rises at the timing T1. In response, a word line which is to be selected transitions to a high level. Further, the column address signal 0, which is a selecting side, transitions to a high level. The column address signal 1, which is a non-selecting side, remains at a low level.

As the column selection signal 0 became a high level, the precharge circuit 40-1 blocks precharge. That is, the precharge circuit 40-1 performs control so that one of the potentials of the BL0 and /BL0 that constitute the bit line pair 0 becomes a low level. Meanwhile, as the column selection signal 1 remains at a low level, the precharge circuit 40-2 continues the precharge operation.

The timing generation circuit 10 switches the read enable signal to a high level at the timing T2, which is when the replica bit line signal output at the timing Ti returns (is input) to the timing generation circuit 10.

The data latch circuit 70-1 performs read processing at the timing T3, which is after the read enable signal becomes a high level. When the data reading is completed, the column address signal 0 and the read enable signal transition to a low level.

Next, an advantage of the semiconductor apparatus 1 according to this embodiment shall be explained. The semiconductor apparatus 1 according to this embodiment blocks precharge of only the selected bit line pair. Since the precharge of only the bit line pair which is to be selected is blocked, it is possible to achieve an advantage such as an improvement in stability of the memory cells and avoidance of an inrush current. Further, as the precharge of only the bit line pair which is to be read is blocked, the potentials of the bit line pairs which will not be read stay the same, and only the potential of one bit line that constitutes the bit line pair which is to be read changes. This is when the potential of which bit line between the bit line pair changes is determined according to the data (bit value) which is to be read. That is, by referring to a change in potentials of the bit lines, it is possible to know the data which will be read. Using this property, the data latch circuit 70 performs a logical operation (NAND) using the potential of the bit line pair, thereby outputting the read data. In other words, the data latch circuit 70 reads the data without using the column address signal. Thus, the configuration of the semiconductor apparatus 1 according to this embodiment does not require a circuit to handle the column address signal, thereby making it possible to reduce the number of circuit elements.

Second Embodiment

A semiconductor apparatus 1 according to this embodiment is characterized in that the data latch circuit 70 and the write driver 50 are separately disposed. A difference between the semiconductor apparatus 1 of the second embodiment and the semiconductor apparatus 1 of the first embodiment shall be explained below. Note that in the drawings, the processing units (circuits) denoted by the same name and numeral as those in the first embodiment shall correspond to those in the first embodiment unless otherwise specified.

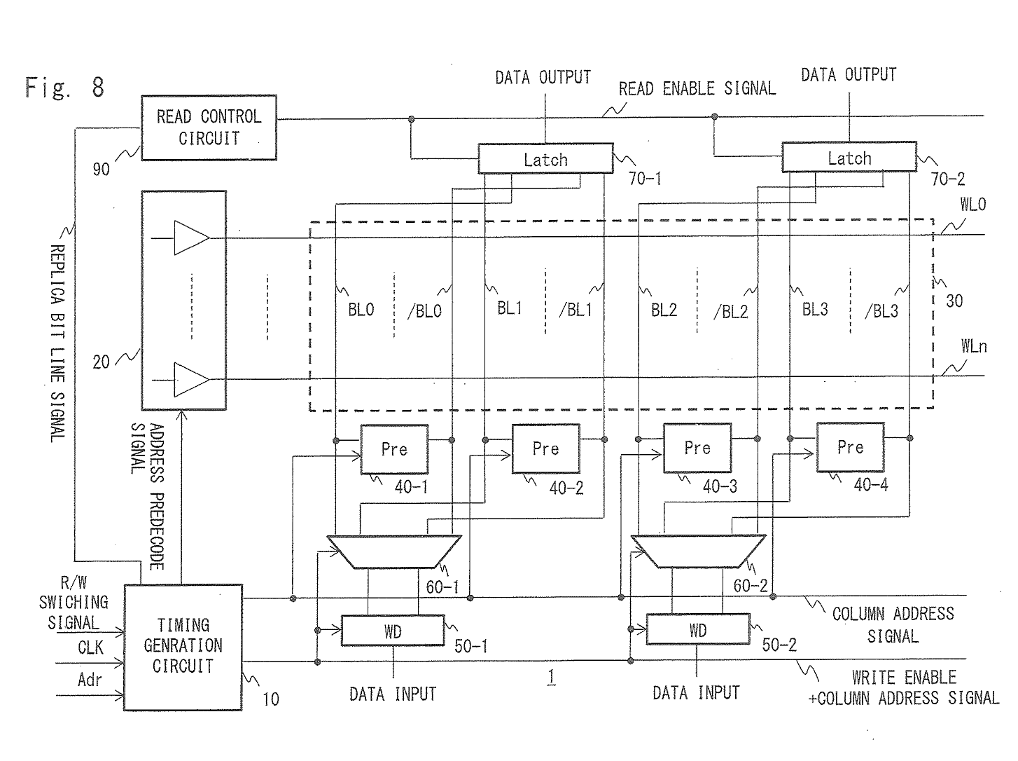

FIG. 8 is a block diagram showing a configuration of the semiconductor apparatus 1 according to this embodiment. As shown in FIG. 8, the data latch circuit 70 and the write driver 50 are disposed to sandwich the memory array 30.

When a read request is generated, the timing generation circuit 10 supplies the replica bit line signal to the read control circuit 90. After the replica bit line signal is supplied, the read control circuit 90 transitions the read enable signal to a high level and supplies the read enable signal to the data latch circuits 70-1 and 70-2.

As shown in the drawing, it is preferable that the write driver 50 be disposed physically closer to the timing generation circuit 10 (i.e., a lower region in the drawing). In other words, it is preferable that a wiring length connecting the timing generation circuit 10 to the closest write driver 50 (the write driver 50-1 in the drawing) be configured to be less than a wiring length connecting the timing generation circuit 10 to the read control circuit 90. The reason for such a configuration shall be explained below.

In the case of writing in the memory array 30, it is desirable that the write processing be performed immediately. Meanwhile, in the case of reading from the memory array 30, as the precharge is blocked, it is necessary to wait until one of the bit lines between the bit line pair becomes a high level and the other bit line becomes a low level before reading. By the above-mentioned arrangement (the write driver 50 is disposed physically closer to the timing generation circuit 10), it is possible to promptly write and to adjust a timing of reading.

Note that the wiring length connecting the read control circuit 90 to the timing generation circuit 10 (i.e., a replica bit line signal path) is a wiring length that generates a delay that corresponds to the time from when the precharge block is started until it is ended (until the potential of one bit line is switched to a low level). In this manner, a read timing is adjusted.

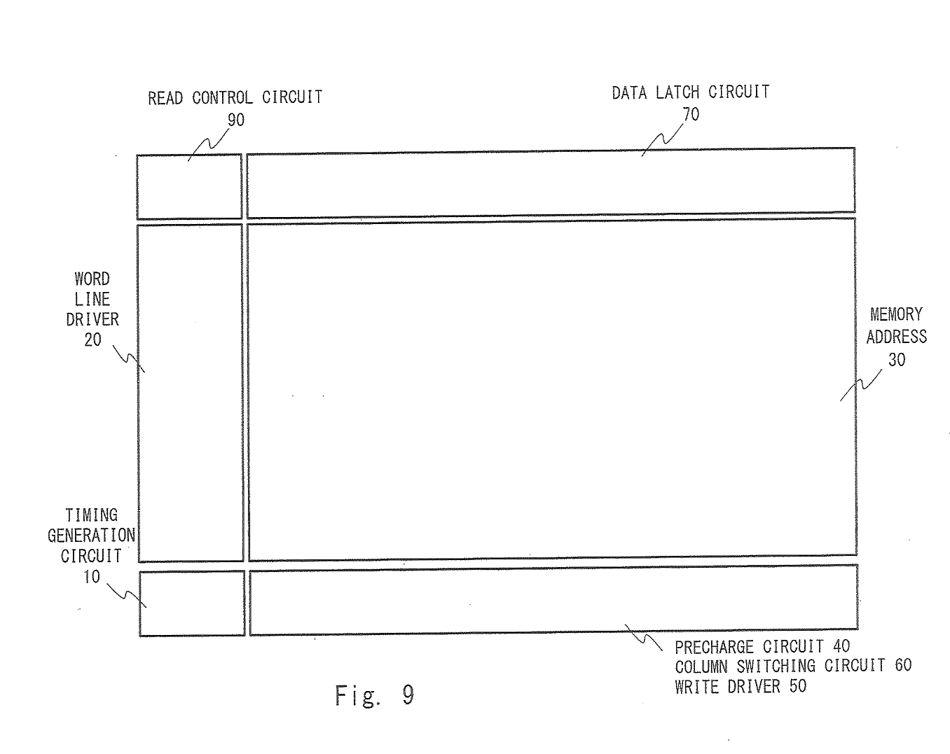

FIG. 9 is a layout image when the circuit configuration shown in FIG. 8 is arranged on a chip. As shown in FIG. 9, the data latch circuit 70 and the write driver 50 and the like are arranged to sandwich the memory array 30. Note that FIG. 9 is a diagram showing an arrangement of the layout and sizes of the regions in FIG. 9 do not indicate the physical sizes of the regions.

Next, an advantage of the semiconductor apparatus 1 according to this embodiment shall be explained. In the configuration of the first embodiment, the data latch circuit 70 and the write driver 50 are arranged in the lower part of the drawing of the memory array 30. Therefore, input and output terminals are concentrated in a lower region of the memory array 30, that is, near a part of the region of the memory array 30.

Meanwhile, in the semiconductor apparatus 1 according to this embodiment, as shown in FIGS. 8 and 9, the data latch circuit 70 and the test driver 50 are arranged to sandwich the memory array 30. In this manner, the input and output terminals are distributed in the upper and lower regions of the memory array 30, thereby improving flexibility of wiring.

Other Embodiment

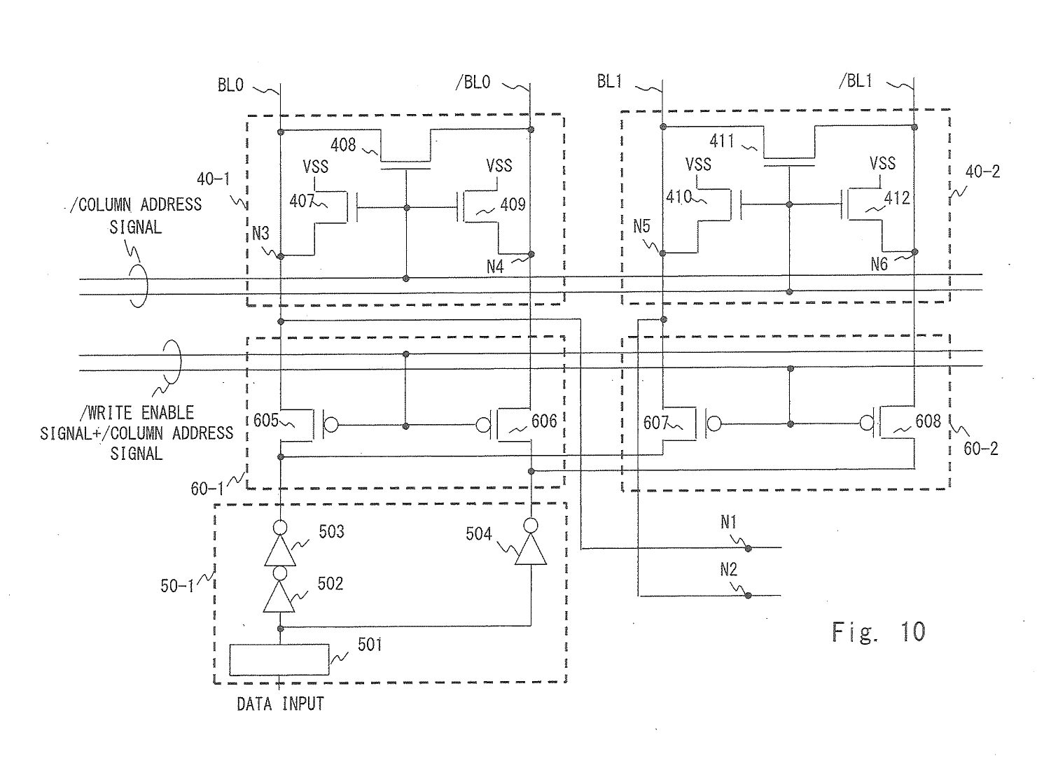

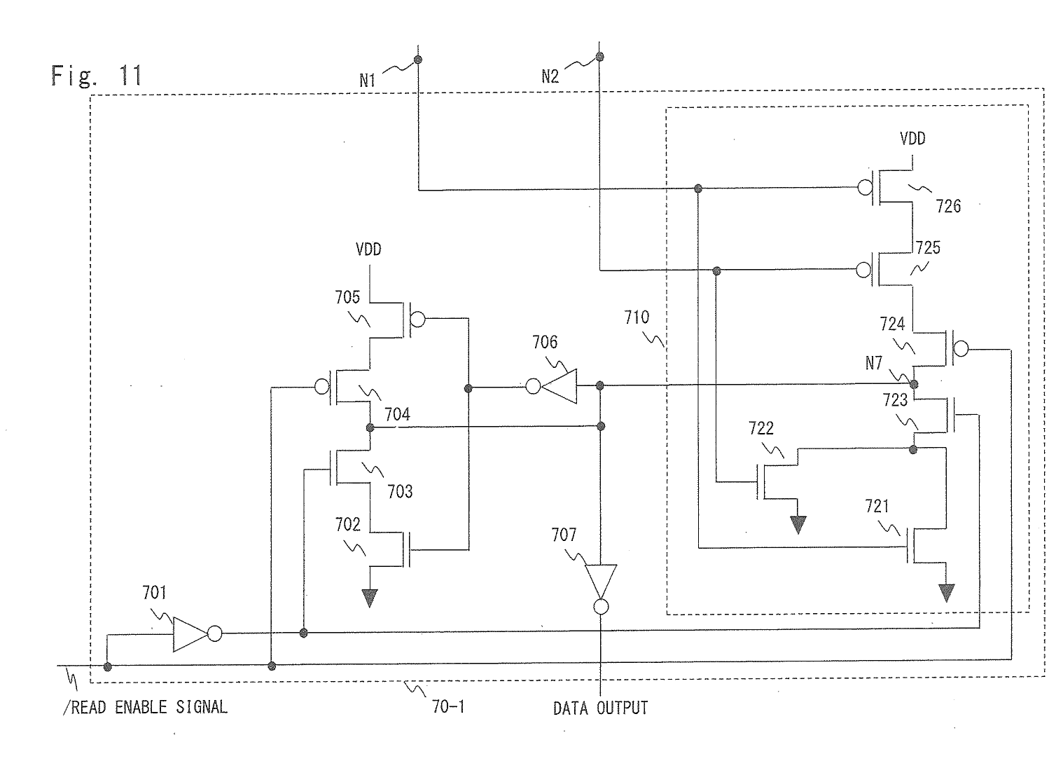

The above-mentioned semiconductor apparatus 1 can have the configuration shown in, for example, FIG. 10 or 11. FIGS. 10 and 11 show a configuration in which the precharge circuit 40 performs so-called row-precharge. In this case, two access MOS transistors (MN3 and MN4) of memory cell shown in FIG. 4 are changed to PMOS. A difference between this embodiment and the first embodiment shall be explained below.

FIG. 10 is a diagram showing a modified example of the precharge circuit 40, the write driver 50, and the column switching circuit 60. Unlike the configuration of FIG. 5, the column switching circuit 60-1 is composed of a PMOS 605 and a PMOS 606. Similarly, the column switching circuit 60-2 is composed of a PMOS 607 and a PMOS 608. An inverted signal of the write enable signal and an inverted signal of the column address signal are input to the gates of the PMOSs 605 to 608.

Unlike the configuration of FIG. 5, the precharge circuit 40-1 is composed of NMOSs 407 to 409. Similarly, the precharge circuit 40-2, unlike the configuration of FIG. 5, is composed of NMOSs 410 to 412. An inverted signal of the column address signal is input to the gates of the NMOSs 407 to 412.

Even with this configuration, precharge of only one bit line pair that is connected to the data latch circuit 70-1 is blocked, while precharge of other bit line pairs continues.

FIG. 11 is a diagram showing a modified example of the data latch circuit 70 corresponding to the configuration of FIG. 10. In comparison to the configuration of FIG. 6, the configuration of the data latch circuit 70-1 shown in FIG. 11 has a different internal configuration of the NAND gate 710. Further, an inverted signal of the read enable signal is input to the data latch circuit 70-1.

The data latch circuit 70-1 includes a NOT circuit 701, an NMOS 702, an NMOS 703, a PMOS 704, a PMOS 705, a NOT circuit 706, a NOT circuit 707, and an NAND gate 710. The configuration of the data latch circuit 70-1 is the same as the circuit configuration shown in FIG. 6, except for the internal configuration of the NAND gate 710.

NAND gate 710 includes NMOSs 721 to 723 and PMOSs 724 to 726. The NMOS 721 is disposed between the GND and the NMOS 722 and the NMOS 723. As the gate of the NMOS 721 is connected to the node N1 (i.e., the bit line BL0), when the node N1 is a high level, the NMOS 721 is switched on.

The NMOS 722 is disposed between the GND and the NMOS 721 and the NMOS 723. As the gate of the NMOS 722 is connected to the node N2 (i.e., the bit line BL1), when the node N2 is a high level, the NMOS 722 is switched on.

The NMOS 723 is disposed between the NMOS 721 and the NMOS 722 and the node N7. As the read enable signal (to be precise, a value obtained by inverting the inverted signal of the read enable signal using the NOT 701) is input to the gate of the NMOS 723, when the read enable signal is a high level, the NMOS 723 is switched on.

The PMOS 724 is disposed between the node N7 and the PMOS 725. As an inverted signal of the write enable signal is input to the gate of the PMOS 724, when the read enable signal is a high level, the PMOS 724 is switched on.

The PMOS 725 is disposed between the PMOS 724 and the PMOS 726. As the gate of the PMOS 725 is connected to the node N2, when the node N2 is a low level, the PMOS 725 is switched on.

The PMOS 726 is disposed between the power supply terminal VDD and the PMOS 725. As the gate of the PMOS 726 is connected to the node N1, when the node Ni is a low level, the PMOS 726 is switched on.

Even with the configurations shown in FIGS. 10 and 11, in a similar manner to the semiconductor apparatus 1 according to the first embodiment, it is not necessary to provide a column selection circuit for reading data. Therefore, it is possible to reduce the number of circuit elements.

Although the invention made by the present inventor has been explained in detail based on the embodiments, the present invention is not limited to the embodiments that have been already explained, but obviously various modifications can be made without departing from the scope of the invention.

For example in the above explanation, although two pairs of bit line pairs are associated with one data latch circuit 70, it is not limited to this. That is, the power of two (e.g., 2, 4, and 8) of the bit line pairs may be associated with one data latch circuit.

The first and second embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor apparatus comprising:
a memory array that is disposed such that bit line pairs are arranged in a plurality of columns in a column direction and the bit line pairs in the plurality of columns are connected to one data latch circuit, a plurality of memory cells being connected to the bit line pair;
a precharge circuit that blocks precharge of a bit line pair that is selected by a column address signal among the plurality of bit line pairs and precharges the bit line pairs other than the bit line pair selected by the column address signal; and
a data latch circuit that outputs read data from the memory array based on potentials of a first bit line and a second bit line, the first bit line constituting a first bit line pair included in the plurality of bit line pairs, and the second bit line pair constituting a second bit line pair included in the plurality of bit line pairs.

2. The semiconductor apparatus according to claim 1, wherein
when a read enable signal indicating a read instruction is input from the memory array, the data latch circuit outputs an inverted value of an NAND value between the potential of the first bit line and the potential of the second bit line as the read data from the memory array.

3. The semiconductor apparatus according to claim 1, wherein a layout is configured in such a way that the memory array is disposed between a write driver that writes data in the memory array and the data latch circuit.

4. The semiconductor apparatus according to claim 3, further comprising:
a timing generation circuit that outputs a replica bit line signal after receiving a read request signal to the memory array from an external circuit; and
a read control circuit that outputs a read enable signal after receiving the replica bit line signal, the read enable signal instructing the data latch circuit to start read processing,
wherein a wiring length connecting the timing generation circuit to the read control circuit is greater than a wiring length connecting the timing generation circuit to the write driver.

5. The semiconductor apparatus according to claim 1, further comprising a timing generation circuit that receives a read request signal to the memory array from an external circuit, outputs a replica bit line signal on loop wiring after receiving the read request signal, and outputs a read enable signal for instructing the data latch circuit to start read processing after the replica bit line signal is input.

6. The semiconductor apparatus according to claim 1, wherein the precharge circuit is configured to perform row precharge.

7. A method of reading data from a memory array that is disposed such that bit line pairs are arranged in a plurality of columns in a column direction and a plurality of the bit line pairs are connected to one data latch circuit, a plurality of memory cells being connected to the bit line pair, the method comprising:
blocking precharge of a bit line pair that is selected by a column address signal among the plurality of bit line pairs and precharging the bit line pairs other than the bit line pair selected by the column address signal;
outputting read data from the memory array based on potentials of a first bit line and a second bit line, the first bit line constituting a first bit line pair included in the plurality of bit line pairs, and the second bit line pair constituting a second bit line pair included in the plurality of bit line pairs.
